(19) United States
(12) Patent Application Publication
(10) Pub. No.: US 2026/0182276 A1
(43) Pub. Date: Jun. 25, 2026

(54) METHOD FOR TREATING SUBSTRATES

(71) Applicant: Soitec, BERNIN (FR)

(72) Inventors: Isabelle Bertrand, BERNIN (FR); Djamel Belhachemi, BERNIN (FR); Didier Landru, BERNIN (FR); Dorothée Giraud, BERNIN (FR); Odile Mourey, BERNIN (FR)

(21) Appl. No.: 18/727,189

(22) PCT Filed: Jan. 5, 2023
(86) PCT No.: PCT/EP2023/050191

§ 371 Date: Jul. 8, 2024

(30) Foreign Application Priority Data
Jan. 7, 2022 (FR) 2200119

(51) Int. Cl. H10P 36/00; H10N 30/01

(52) U.S. Cl. CPC H10P 36/03; H10N 30/01

(57) ABSTRACT

A method for treating substrates comprises: a step of treating a first substrate comprising at least one step carried out in an apparatus carrying out a thermal treatment, the first substrate being a substrate made of a semiconductor material or of a piezoelectric material; a step of decontaminating the apparatus carrying out a thermal treatment by a thermal treatment of a decontamination substrate, in particular, a silicon substrate; and then a step of treating a second substrate comprising at least one step carried out in the apparatus carrying out a thermal treatment, the first substrate being a substrate made of a semiconductor material or of a piezoelectric material.

### CROSS-REFERENCE TO RELATED APPLICATIONS

This application is a national phase entry under 35 U.S.C. §371 of International Patent Application PCT/EP2023/050191, filed Jan. 5, 2023, designating the United States of America and published as International Patent Publication WO 2023/131654 A1 on Jul. 13, 2023, which claims the benefit under Article 8 of the Patent Cooperation Treaty of French Patent Application Serial No. FR2200119, filed Jan. 7, 2022.

### TECHNICAL FIELD

The present disclosure relates to a process for the treatment of substrates and more particularly to a process for the treatment of semiconductor substrates and/or of piezoelectric substrates.

### BACKGROUND

During heat treatments in processes using semiconductor and/or piezoelectric substrates, the diffusion of a metal element, such as, for example, lithium, can result in contamination of the item of equipment carrying out the heat treatment, such as an oven. The level of contamination by this element can, for example, be determined by VPD-ICPMS (from Vapor Phase Decomposition and Inductively Coupled Plasma Mass Spectrometry) as number of atoms per square centimeter. The level of contamination can depend on the number of cycles carried out with substrates comprising the metal element, on the conditions of the process used and on the type of substrate used. A strong increase in the level of contamination is, in particular, observed when a substrate breaks inside the item of equipment. A high level of contamination in an item of equipment may subsequently reduce the production yield.

The contamination problem can also have a negative impact on the production lines of a manufacturer as contamination by a certain element in an item of equipment can result in a ban on carrying out various types of processes on one and the same item of equipment, which greatly reduces the flexibility of manufacture and requires the manufacturer to install several separate manufacturing lines according to the process and the materials used.

The object of the present disclosure is thus the installation of a decontamination process, which makes it possible to reduce the level of contamination by a metal element in an item of equipment carrying out a heat treatment.

The object of the present disclosure is achieved with a process for the treatment of substrates comprising: a stage of treatment of a first substrate comprising at least one stage carried out in an item of equipment carrying out a heat treatment, the first substrate being a substrate comprising a semiconductor material or a piezoelectric material, subsequently a stage of reduction in the level of contamination of the item of equipment by a contaminating metal element by carrying out a heat treatment of a decontamination substrate, in particular, a silicon-based substrate, more particularly still a substrate made of mono-or polycrystalline silicon, of porous silicon or of SiOCH, and subsequently a stage of treatment of a second substrate comprising at least one stage carried out in the item of equipment carrying out a heat treatment, the second substrate being a substrate comprising a semiconductor material or a piezoelectric material. Measurements by VPD-ICPMS have shown that the use of such a decontamination substrate during the decontamination stage makes it possible to reduce the level of contamination in the item of equipment.

### BRIEF SUMMARY

According to one embodiment, the decontamination substrate used for the stage of reduction in the level of contamination is a dedicated substrate for the decontamination stage and only used for this decontamination stage. The decontamination substrate is thus not present in the item of equipment carrying out a heat treatment during the stages of heat treatment of the first substrate and of the second substrate. Likewise, neither the first substrate nor the second substrate is present in the item of equipment carrying out a heat treatment during the decontamination stage.

According to one embodiment, the first and the second substrate can be of different materials. According to one embodiment, the first substrate can be a piezoelectric substrate chosen from lithium niobate (LiNbO₃) and lithium tantalate (LiTaO₃) and/or the second substrate can be a semiconductor substrate chosen from silicon, silicon carbide (SiC), sapphire (Al₂O₃) or a III-V semiconductor substrate, in particular, gallium arsenide (GaAs). By using a decontamination substrate, it thus becomes possible to use the same item of equipment carrying out a heat treatment for two different types of substrates. Thus, different types of products, such as substrates of silicon-on-insulator (SOI) and piezoelectric-on-insulator (POI) type can be produced using the same item of equipment.

According to one embodiment, the contaminating metal element is lithium. The presence of lithium is banned in processes of silicon type and even in processes using lithium niobate (LiNbO₃) or lithium tantalate (LiTaO₃) substrates, alone or in combination with silicon-based substrates, an excessively high level of lithium can result in a fall in production yield. The process according to the present disclosure is effective in reducing the level of lithium in the item of equipment.

According to one embodiment, the process can comprise, before and/or after the decontamination stage, a stage of determination of the level of contamination of at least one contaminating component inside the item of equipment carrying out a heat treatment. The knowledge of the level of contamination, for example, by carrying out VPD-ICPMS measurements on a decontamination substrate, makes it possible to adjust the parameters of the implementation of the decontamination stage, for example, the duration, the temperature and/or the atmosphere applied, or to confirm the result of the decontamination stage.

According to one embodiment, the decontamination stage can be carried out if the level of contamination exceeds a predetermined contamination threshold. Thus, the decontamination stage may only be carried out if necessary.

According to one embodiment, the decontamination stage can be carried out at a temperature of at least 500° C., in particular, at least 800° C. The decontamination effect is more effective starting from these temperatures.

According to one embodiment, the decontamination stage can be carried out under an oxidizing atmosphere, in particular, by introducing oxygen. The decontamination effect is more effective under an oxidizing atmosphere.

According to one embodiment, the decontamination stage can be carried out for a predetermined period of time, in particular, for at least 30 minutes, more particularly for at least 1 hour. These periods of time make possible an even more effective decontamination.

According to one embodiment, the decontamination stage can be repeated before continuing with the stage of treatment of the second substrate at least once, a fresh decontamination substrate being used, in particular, at each repetition. The repetition of the stage with a new decontamination substrate makes it possible to increase the effectiveness of the decontamination.

According to one embodiment, the decontamination substrate can be discarded after the heat treatment. Thus, the risk of recontamination of the item of equipment is reduced.

The object of the present disclosure is also achieved by the use of a silicon substrate as a decontamination substrate in a process as described above. All the advantages of the process as described above can be produced by the use of a silicon substrate.

### BRIEF DESCRIPTION OF THE DRAWINGS

The present disclosure and its advantages will be explained in more detail subsequently by way of advantageous exemplary embodiments and with the support, in particular, of the following accompanying figure, in which the reference numbers identify characteristics of the present disclosure.

FIG. 1 diagrammatically represents a process for the treatment of a substrate according to one embodiment.

### DETAILED DESCRIPTION

The present disclosure will be described in more detail using advantageous embodiments in an exemplary way and with reference to the drawings. The embodiments described are simply possible configurations and it should be kept in mind that the individual characteristics as described above can be provided independently of one another or can be omitted entirely during the implementation of the present disclosure.

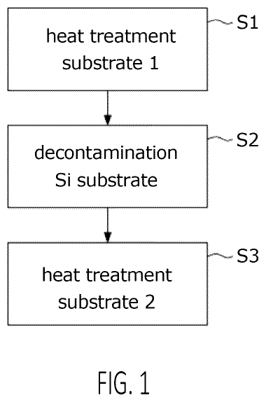

FIG. 1 diagrammatically represents a process for the treatment of a substrate according to one embodiment.

During stage S1, a heat treatment is carried out on a first substrate in an item of equipment carrying out a heat treatment. The first substrate is a substrate comprising a semiconductor material or a piezoelectric material.

According to the process of the first embodiment, the first substrate is a piezoelectric substrate chosen from lithium niobate (LiNbO₃) and lithium tantalate (LiTaO₃). The item of equipment can, for example, be an oven for heating one or more substrates, or a deposition reactor, for example, a chemical vapor deposition (CVD) reactor.

The heat treatment can be an annealing treatment, a heat treatment necessary during a layer deposition, a fracturing treatment during a process for transfer of layer onto a support substrate for producing a POI substrate, for example, a process such as known under the SMARTCUT® name, or any treatment requiring a temperature greater than ambient temperature, that is to say a temperature of approximately 20° C. to 25° C. Treatments at temperatures above 500° C. are particularly relevant.

It is known that contamination of an item of thermal equipment by lithium atoms can take place following phenomena of diffusion during such a heat treatment. The level of contamination in the item of equipment depends on the number of cycles carried out with first substrates, on the conditions of the process used and on the type of first substrate used. A strong increase in the contamination is observed when a substrate breaks inside the item of equipment, whether accidentally or deliberately, for example, during a fracturing stage.

According to the present disclosure, a decontamination stage S2 is subsequently carried out to reduce the level of contamination in the item of equipment carrying out the heat treatment. To reduce the presence of lithium in the item of equipment, a decontamination substrate is introduced into the item of equipment. According to the first embodiment, a silicon substrate is used. It is a silicon wafer, with or without its natural oxide. The silicon substrate is introduced at a temperature of approximately 350° C. and is subsequently heated to at least 500° C., preferably to at least 800° C. This temperature is maintained for at least 30 minutes, preferably for at least one hour. This decontamination stage is carried out under an oxidizing atmosphere, in particular, by introducing oxygen into the item of equipment.

The decontamination substrate is subsequently discarded to prevent fresh contamination during reintroduction into the item of equipment.

VPD-ICPMS measurements were applied to a fresh silicon substrate introduced into the item of equipment after stage S2 and heated in the same way to at least 500° C., preferably at least 800° C., under an oxidizing atmosphere for at least 30 minutes, preferably at least 1 hour. These measurements showed a fall in the surface density of lithium, in comparison with the same measurement on the silicon substrate used during stage S2. The VPD-ICPMS measurements operate as follows: decomposition of the natural oxide layer by etching, in particular, by using HF in the vapor phase, after sweeping the surface with 150 μl of an HF/HNO₃ solution and subsequent dilution of this solution in 250 μl of an HF/HNO₃ solution before the ICPMS analysis.

After the decontamination stage S2, the process is continued with stage S3, which is a process for treatment of a second substrate. The second substrate can be a substrate comprising a semiconductor material or a piezoelectric material. It can be the same material as for the first substrate or another material.

If the same material is used, the treatment of the second substrate can be the same as for the first substrate, or another.

If another material is used, it can, by way of example, be a semiconductor substrate chosen from silicon, silicon carbide (SiC), sapphire (Al₂O₃) or a III-V semiconductor substrate, in particular, gallium arsenide (GaAs).

The treatment of the second substrate comprises at least one stage carried out also in the item of equipment carrying out the heat treatment. Given that the item of equipment has been decontaminated beforehand, the quality of the treatment of the second substrate is not impacted, or is less impacted by the contaminant, which is lithium in this example. This makes it possible to obtain a gain in yield, in comparison with a process without the decontamination stage. As for the first substrate, the heat treatment can be an annealing treatment, a heat treatment necessary during a layer deposition, a fracturing treatment during a process for transfer of layer onto a support substrate for producing an SOI substrate, for example, a process such as that known under the SMARTCUT® name, or any other treatment requiring a temperature greater than ambient temperature, that is to say a temperature of approximately 20° C. to 25° C. Treatments at temperatures above 500° C. are particularly relevant.

The decontamination substrate used for stage S2 of reduction in the level of contamination is a dedicated substrate for the decontamination stage and only used for this decontamination stage. The decontamination substrate is thus not present in the item of equipment carrying out a heat treatment during the stages S1 and S2 of heat treatment of the first substrate and of the second substrate. Likewise, neither the first substrate nor the second substrate is present in the item of equipment carrying out a heat treatment during the decontamination stage S2.

According to an alternative form of the process according to the present disclosure, the decontamination stage S2 is repeated before continuing with stage S3 at least once, a fresh decontamination substrate being used at each repetition. Thus, the level of decontamination of the item of equipment can be further improved because, at each repetition of stage S2, contaminating elements are captured in the decontamination substrate. Thus, it becomes possible to reduce the level of contamination below a detection limit of the VPD-ICPMS measurement device. According to another alternative form, process S2 is repeated if the contamination measured by VPD-ICPMS exceeds a predetermined contamination threshold value, for example, 1×10¹³ at/cm². Instead of using VPD-ICPMS, it is also possible to measure the contamination by secondary ion mass spectrometry (also called “SIMS”). The process according to the present disclosure makes it possible to reduce the contamination of an item of heat treatment equipment, such as an oven, in a way that is effective and simple to carry out using silicon substrates. Depending on the level of decontamination desired, the process can be repeated before continuing with the use of the item of equipment in the following manufacturing process.

1. A method of treating substrates, comprising:
a stage of treating a first substrate comprising at least one stage carried out in an item of equipment carrying out a heat treatment, the first substrate being a substrate comprising a semiconductor material or a piezoelectric material;
subsequently, a decontamination stage of reduction in a level of contamination of the item of equipment by a contaminating metal element by carrying out a heat treatment of a decontamination substrate; and
subsequently, a stage of treating a second substrate comprising at least one stage carried out in the item of equipment, the second substrate being a substrate comprising a semiconductor material or a piezoelectric material.

2. The method of claim 1, wherein the first and the second substrate are of different materials.

3. The method of claim 2, wherein the first substrate is a piezoelectric substrate chosen from lithium niobate (LiNbO₃) and lithium tantalate (LiTaO₃) and/or the second substrate is a semiconductor substrate chosen from silicon, silicon carbide (SiC), sapphire (Al₂O₃) or a III-V semiconductor substrate.

4. The method of claim 1, wherein the contaminating metal element is lithium.

5. The method of claim 1, further comprising, before and/or after the decontamination stage, a stage of determination of the level of contamination of the at least one contaminating metal element inside the item of equipment.

6. The method of claim 5, wherein the decontamination stage is carried out in response to the level of contamination exceeding a predetermined contamination threshold.

7. The method of claim 1, wherein the decontamination stage is carried out at a temperature of at least 500° C.

8. The method of claim 1, wherein the decontamination stage is carried out under an oxidizing atmosphere.

9. The method of claim 1, wherein the decontamination stage is carried out for a predetermined period of time.

10. The method of claim 1, further comprising repeating the decontamination stage at least once before carrying out the stage of treating the second substrate.

11. The method of claim 1, further comprising discarding the decontamination substrate after the heat treatment of the decontamination substrate.

12. (canceled)

13. The method of claim 1, wherein the decontamination substrate comprises a silicon-based substrate.

14. The method of claim 13, wherein the silicon-based substrate is a monocrystalline substrate, a polycrystalline substrate, or a porous substrate.

15. The method of claim 14, wherein the silicon-based substrate is a silicon substrate.

16. The method of claim 14, wherein the silicon-based substrate comprises SiOCH.

17. The method of claim 7, wherein the decontamination stage is carried out at a temperature of at least 800° C.

18. The method of claim 8, further comprising introducing oxygen into the item of equipment to form the oxidizing atmosphere.

19. The method of claim 9, wherein the predetermined period of time is at least 30 minutes.

20. The method of claim 19, wherein the predetermined period of time is at least 1 hour.

21. The method of claim 10, further comprising using a fresh decontamination substrate during each repetition.
